(19) United States
(12) Patent Application Publication
(10) Pub. No.: US 2019/0096670 A1
(43) Pub. Date: Mar. 28, 2019

(54) METHOD FOR MANUFACTURING LOW-TEMPERATURE POLY-SILICON THIN FILM TRANSISTOR

(71) Applicant: WUHAN CHINA STAR OPTOELECTRONICS TECHNOLOGY CO., LTD., Wuhan, Hubei (CN)

(72) Inventor: Songshan LI, Wuhan, Hubei (CN)

(73) Assignee: WUHAN CHINA STAR OPTOELECTRONICS TECHNOLOGY CO., LTD., Wuhan, Hubei (CN)

(21) Appl. No.: 15/539,962

(22) PCT Filed: May 4, 2017
(86) PCT No.: PCT/CN2017/083060

§ 371 Date: Jun. 26, 2017

(30) Foreign Application Priority Data
Apr. 17, 2017 (CN) 201710249455.0

(51) Int. Cl. H01L 21/02; H01L 29/49; H01L 29/66; H01L 29/786

(52) U.S. Cl. CPC H01L 21/02595; H01L 21/02532; H01L 21/02675; H01L 29/786; H01L 29/4908; H01L 29/66765; H01L 21/02669

(57) ABSTRACT

Disclosed is a method for manufacturing a low-temperature poly-silicon thin film transistor, which relates to the technical field of display panel. The method comprises steps of: forming a gate layer, an active layer, a source-drain contact layer and a source-drain electrode in sequence on a substrate. The step of forming the source-drain contact layer includes sub steps of: forming a channel protection layer; depositing an ohmic contact layer using a reaction gas containing diborane and through a plasma enhanced chemical vapor deposition method; and patterning the ohmic contact layer to form the source-drain contact layer. During deposition of the ohmic contact layer, boron ions can enter into the source-drain contact layer. According to this method, a mask is not needed to define an implanted region of boron ions. Therefore, a procedure of implanting the boron ions can be saved; the manufacturing procedure can be simplified; and the manufacturing cost can be reduced.

### CROSS-REFERENCE TO RELATED APPLICATIONS

This application claims the priority of Chinese patent application CN 201710249455.0, entitled “Method for manufacturing low-temperature poly-silicon thin film transistor” and filed on Apr. 17, 2017, the entirety of which is incorporated herein by reference.

### FIELD OF THE INVENTION

The present disclosure relates to the technical field of display panel, and in particular, to a method for manufacturing a low-temperature poly-silicon thin film transistor.

### BACKGROUND OF THE INVENTION

In pixel units of various display devices, thin film transistors (TFT) for driving the display devices by applying driving voltages are widely used. An amorphous silicon (a-Si) material with good stability and workability is always used in an active layer of a TFT. However, carrier mobility of a-Si material is quite low, which cannot meet the requirements of large size and high resolution display devices, especially the requirements of the next generation active matrix organic light emitting display devices.

Compared with a-Si, low-temperature poly-silicon (LTPS) has attracted widespread attention in recent years due to its many advantages, such as high electron mobility, good sub-threshold swing, large on-off current ratio, low power consumption, the capacity of manufacturing high-density pixels, the applicability on a substrate of a flexible organic light-emitting diode (OLED). However, during the manufacturing of a low-temperature poly-silicon thin film transistor (LTPS-TFT), a mask is needed to define a source-drain contact region, and then boron is implanted therein by an ion implanter. Next, the source-drain contact region can be formed after activation by high-temperature rapid annealing. The manufacturing procedure is complicated and the manufacturing cost is high. Hence, how to simplify the manufacturing procedure of LTPS-TFT and reduce the manufacturing cost thereof becomes an urgent problem to be solved.

### SUMMARY OF THE INVENTION

Aiming at the technical problem that how to simplify the manufacturing procedure of low-temperature poly-silicon (LTPS) and reduce the manufacturing cost thereof in the prior art, the present disclosure provides a method for manufacturing a low-temperature poly-silicon thin film transistor (LTPS-TFT).

The method for manufacturing low-temperature poly-silicon thin film transistor provided by the present disclosure comprises steps of:

S11: forming a gate layer on a substrate;

S12: forming an active layer;

S13: forming a source-drain contact layer; and

S14: forming a source-drain electrode layer,

wherein the step of forming the source-drain contact layer comprises:

forming a channel protective layer, depositing an ohmic contact layer by a plasma enhanced chemical vapor deposition method, wherein a reaction gas contains diborane, and patterning the ohmic contact layer to form the source-drain contact layer.

The source-drain contact layer is formed by the aforesaid method. Since the reaction gas contains diborane, boron ions can enter into the ohmic contact layer during deposition of the ohmic contact layer through the plasma enhanced chemical vapor deposition (PECVD) method. In this manner, the source-drain contact layer formed therein contains boron ions. Therefore, an impedance of the source-drain contact layer is reduced, and contact impedances thereof with a source and a drain become smaller. According to this method, a mask is not needed to define an implanted region of boron ions. Therefore, a process of implanting the boron ions can be saved; the manufacturing procedure can be simplified; and the manufacturing cost can be reduced.

As a further improvement on the present disclosure, the reaction gas further comprises silane and hydrogen. At this time, the reaction gas is a mixture of silane, hydrogen and diborane.

Further, a material used in the step of depositing the ohmic contact layer comprises P⁺a-Si.

As a further improvement on the present disclosure, the step of forming the channel protection layer comprises sub steps of:

depositing an etching barrier layer on the active layer; and

hydrotreating the etching barrier layer through heating, and patterning the etching barrier layer to form the channel protection layer.

Further, the etching barrier layer comprises at least one of a silicon oxide layer and a silicon nitride layer. The etching barrier layer can be the silicon oxide layer or the silicon nitride layer, or an overlay of the silicon oxide layer and the silicon nitride layer.

As a further improvement on the present disclosure, the step of forming the active layer comprises sub steps of:

depositing a gate insulating layer on an entire surface of the substrate;

depositing an amorphous silicon layer;

transforming the amorphous silicon layer to a poly-silicon layer through an excimer laser annealing procedure; and

patterning the poly-silicon layer to form the active layer.

The poly-silicon layer and ions are activated through the excimer laser annealing procedure. In this manner, the problem that the entire substrate heated by the excimer laser annealing procedure affects a flexible display device can be avoided, which is conducive to realization of flexible display. Besides, lattice integrity of poly-silicon can be improved by local hyperthermia of the excimer laser annealing procedure, so that a performance of the TFT can be improved.

As a further improvement on the present disclosure, the step of forming the gate layer comprises sub steps of: depositing a first metal layer on an entire surface of the substrate; and patterning the first metal layer to form the gate layer. Further, a buffer layer is manufactured on the entire surface of the substrate before the first metal layer is deposited thereon. The buffer layer comprises at least one of a silicon oxide layer and a silicon nitride layer.

A degree of adherence between the gate layer and the substrate can be improved by the buffer layer. Meanwhile, metal ions in the substrate can be prevented from diffusing to the gate layer by the buffer layer, and thus a leakage current can be reduced.

As a further improvement on the gate layer, the gate layer comprises at least one selected from a group consisting of molybdenum, tantalum, aluminum and tungsten. These metals are commonly used metal materials in manufacturing of TFT and are convenient to use.

As a further improvement on the present disclosure, the step of forming the source-drain electrode layer comprises sub steps of: depositing a second metal layer; and patterning the second metal layer to form the source-drain electrode layer. A metal for forming the second metal layer comprises at least one of molybdenum and aluminum.

The present disclosure further provides a low-temperature poly-silicon thin film transistor, which is manufactured through the aforesaid method.

In conclusion, in the method for manufacturing the low-temperature poly-silicon thin film transistor according to the present disclosure, an ohmic contact layer is deposited through PECVD method during the procedure of forming the source-drain contact layer, and meanwhile, the reaction gas used therein contains diborane. In this manner, the boron ions can enter into the source-drain contact layer during deposition of the ohmic contact layer, so that the impedance of the source-drain contact layer can be reduced, and the contact impedances thereof with the source and the drain become smaller. According to this method, a mask is not needed to define an implanted region of boron ions. Therefore, a process of implanting the boron ions can be saved; the manufacturing procedure can be simplified; and the manufacturing cost can be reduced. According to the present disclosure, since the LTPS-TFT is manufactured through the method disclosed herein, the manufacturing cost can be reduced.

### BRIEF DESCRIPTION OF THE DRAWINGS

The present disclosure will be illustrated in detail hereinafter with reference to the embodiments and the accompanying drawings. In the drawings:

FIG. 1 is a flow chart of a method for manufacturing a low-temperature poly-silicon thin film transistor according to the present disclosure;

FIG. 2 schematically shows a structure after a gate layer is formed;

FIG. 3 schematically shows a structure after an active layer is formed;

FIG. 4 schematically shows a structure after a source-drain contact layer is formed;

FIG. 5 schematically shows a structure after a source-drain electrode layer is formed; and

FIG. 6 schematically shows a structure of an array substrate comprising the low-temperature poly-silicon thin film transistor according to the present disclosure.

In the drawings, the same components are represented by the same reference signs, and the size of each component does not represent the actual size of the corresponding component.

### DETAILED DESCRIPTION OF THE EMBODIMENTS

The present disclosure will be described in detail hereinafter with reference to the accompanying drawings. The terms “upper”, “lower”, “right”, and “left” in the following text are directions relative to the directions shown in the drawings, and should not be construed as limiting the scope of the disclosure.

### Embodiment 1

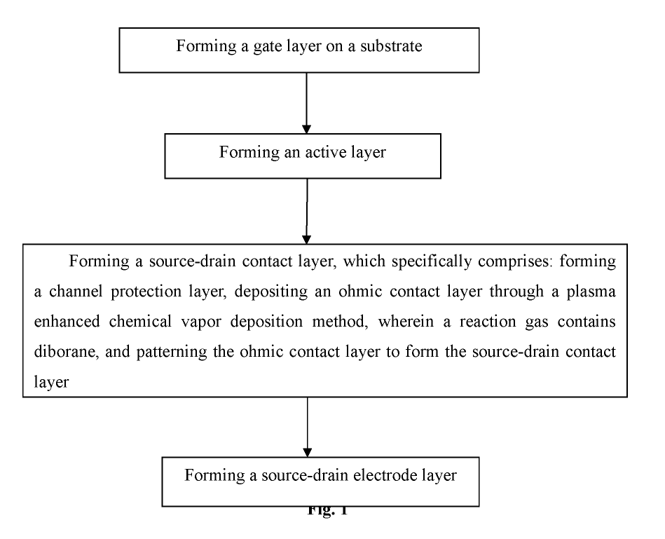

FIG. 1 shows a method for manufacturing a low-temperature poly-silicon thin film transistor according to the present embodiment. The method comprises steps of:

in step S11, a gate layer is formed on a substrate;

in step S12, an active layer is formed;

in step S13, a source-drain contact layer is formed; and

in step S14, a source-drain electrode layer is formed.

Each step will be described in detail below.

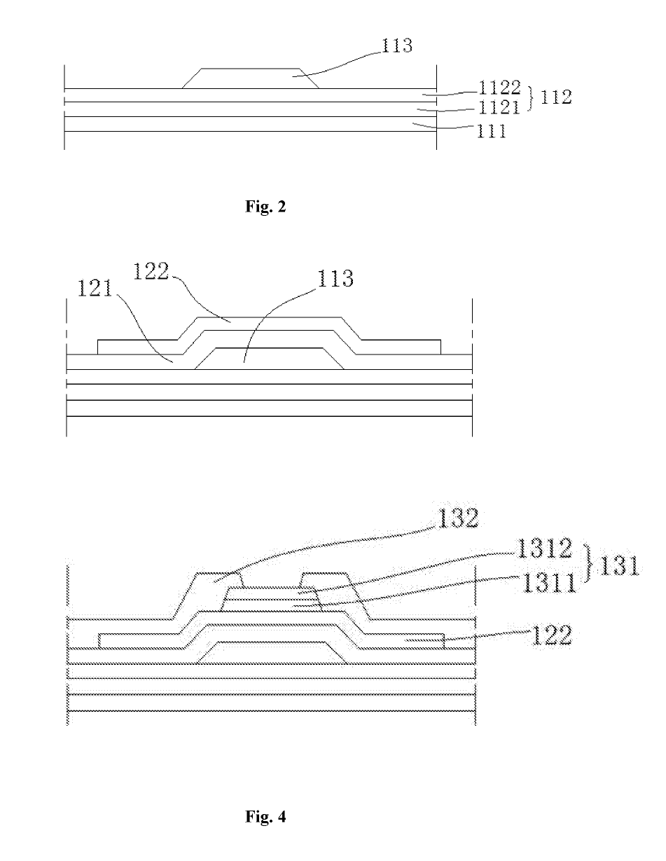

In step S11, the gate layer is formed on the substrate. As shown in FIG. 2, first, a buffer layer 112 is manufactured on an entire surface of a substrate 111, and the buffer layer 112 comprises a silicon nitride layer 1121 and a silicon oxide layer 1122. Of course, according to other embodiments, the buffer layer 112 can comprise only the silicon nitride layer 1121 or the silicon oxide layer 1122. Then, a first metal layer is deposited on the buffer layer 112. Preferably, a material that constitutes the first metal layer is molybdenum. According to other embodiments, the material of the first metal layer can be at least one selected from a group consisting of molybdenum, tantalum, aluminum and tungsten. The first metal layer is patterned through a photographic etching technology to form a gate layer 113.

A degree of adherence between the gate layer 113 and the substrate 111 can be improved by the buffer layer 112. Meanwhile, metal ions in the substrate 111 can be prevented from diffusing to the gate layer 113 by the buffer layer 112, and thus a leakage current can be reduced.

Of course, according to other embodiments, a procedure of forming the buffer layer may not be contained in the procedure of forming the gate layer 113.

In step S12, the active layer is formed. As shown in FIG. 3, a gate insulating layer 121 is deposited on the gate layer 113. Preferably, a material of the gate insulating layer 121 is silicon oxide. Then, an amorphous silicon layer is deposited on the gate insulating layer 121, and the amorphous silicon layer is processed by an excimer laser annealing procedure and transformed to a poly-silicon layer. Next, the poly-silicon layer is patterned to form the active layer 122.

During the procedure, the poly-silicon layer is obtained through the excimer laser annealing procedure. In this manner, the problem that the entire substrate heated by the excimer laser annealing procedure affects a flexible display device can be avoided, which is conducive to realization of flexible display. Besides, lattice integrity of poly-silicon can be improved by local hyperthermia of the excimer laser annealing procedure, so that a performance of the TFT can be improved.

In step S13, the source-drain contact layer is formed. As shown in FIG. 4, an etching barrier layer is deposited on an entire surface of the active layer 122 on the substrate 111. Preferably, the etching barrier layer comprises a silicon oxide layer and a silicon nitride layer. According to other embodiments, the etching barrier layer can comprise only the silicon oxide layer or the silicon nitride layer. The etching barrier layer is hydrogenated through heating, and patterned through the photographic etching technology to form a channel protection layer 131. Since the etching barrier layer in the embodiment comprises the silicon oxide layer and the silicon nitride layer, the channel protection layer 131 comprises a first channel protection layer 1311 and a second channel protection layer 1312.

An ohmic contact layer is deposited on the channel protection layer 131 using a reaction gas containing diborane and through a PECVD method. A material of the ohmic contact layer is preferably P+a-Si, and the reaction gas is preferably a mixture of silane, hydrogen and diborane. Here, the ohmic contact layer is also patterned through the photographic etching technology to form a source-drain contact layer 132. When the reaction gas used therein contains diborane, boron ions can enter into the ohmic contact layer during deposition of the ohmic contact layer through the PECVD method, so that the formed source-drain contact layer contains the boron ions. Therefore, an impedance of the source-drain contact layer can be reduced, and the contact impedances thereof with the source and the drain become smaller. According to this method, a mask is not needed to define an implanted region of boron ions. Therefore, a process of implanting the boron ions can be saved; the manufacturing procedure can be simplified; and the manufacturing cost can be reduced.

When a material of the ohmic contact layer is P⁺a-Si, the thin film transistor manufactured therein is a P-type transistor. Of course, the material of the ohmic contact layer can also be N⁺a-Si, and accordingly, the thin film transistor manufactured therein is an N-type transistor.

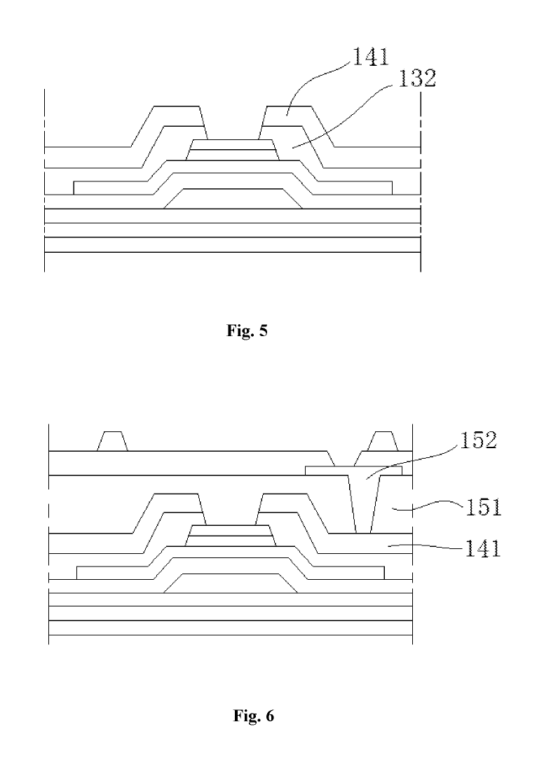

In step S14, the source-drain electrode layer is formed. As shown in FIG. 5, a second metal layer is deposited on the source-drain contact layer 132. Preferably, a material of the second metal layer comprises at least one of molybdenum and aluminum. The second metal layer is patterned through the photographic etching technology to form the source-drain electrode layer 141.

The present disclosure further provides a low-temperature poly-silicon thin film transistor which is manufactured by the aforesaid method.

### Embodiment 2

While manufacturing an array substrate containing the low-temperature poly-silicon thin film transistor manufactured by the aforesaid method, a step S15 is further comprised. As shown in FIG. 6, an organic photoresist planar insulating layer 151 is manufactured on the source-drain electrode layer 141, and then an Anode electrode layer 152 is manufactured. Then a pixel-defining layer (PDL) and a pillar spacer (PS) layer are manufactured.

Finally, it should be noted that, the above embodiments are only used to explain the technical solution of the present disclosure and shall not be construed as limitation.

Although the present disclosure has been described in detail with reference to preferred embodiments, ordinary people skilled in the art should understand that modifications or equivalent substitutions can be made to the technical solutions of the present disclosure. In particular, as long as there are no structural conflicts, the technical features disclosed in each and every embodiment of the present disclosure can be combined with one another in any way, and the combined features formed thereby are within the protection scope of the present disclosure. As long as the technical solutions do not depart from the scope and spirit of the disclosure, all of them shall fall within the scope of the claims.

1. A method for manufacturing a low-temperature poly-silicon thin film transistor, comprising steps of:
S11: forming a gate layer on a substrate;
S12: forming an active layer;
S13: forming a source-drain contact layer; and
S14: forming a source-drain electrode layer,
wherein the step of forming the source-drain contact layer comprises sub steps of:
forming a channel protection layer;
depositing an ohmic contact layer through a plasma enhanced chemical vapor deposition method, wherein a reaction gas contains diborane; and
patterning the ohmic contact layer to form the source-drain contact layer.

2. The method according to claim 1, wherein the reaction gas further comprises silane and hydrogen.

3. The method according to claim 1, wherein a material used in the step of depositing the ohmic contact layer comprises P⁺a-Si.

4. The method according to claim 2, wherein a material used in the step of depositing the ohmic contact layer comprises P⁺a-Si.

5. The method according to claim 1, wherein the step of forming the channel protection layer comprises sub steps of:
depositing an etching barrier layer on the active layer; and
hydrotreating the etching barrier layer through heating, and patterning the etching barrier layer to form the channel protection layer.

6. The method according to claim 2, wherein the step of forming the channel protection layer comprises sub steps of:
depositing an etching barrier layer on the active layer, and
hydrotreating the etching barrier layer through heating, and patterning the etching barrier layer to form the channel protection layer.

7. The method according to claim 5, wherein the etching barrier layer comprises at least one of a silicon oxide layer and a silicon nitride layer.

8. The method according to claim 6, wherein the etching barrier layer comprises at least one of a silicon oxide layer and a silicon nitride layer.

9. The method according to claim 1, wherein the step of forming the active layer comprises sub steps of:
depositing a gate insulating layer on an entire surface of the substrate;
depositing an amorphous silicon layer;
transforming the amorphous silicon layer to a poly-silicon layer through an excimer laser annealing procedure; and
patterning the poly-silicon layer to form the active layer.

10. The method according to claim 1, wherein the step of forming the gate layer comprises sub steps of:
depositing a first metal layer on an entire surface of the substrate; and
patterning the first metal layer to form the gate layer.

11. The method according to claim 10, wherein a buffer layer is manufactured on the entire surface of the substrate before the first metal layer is deposited thereon.

12. The method according to claim 11, wherein the buffer layer comprises at least one of a silicon oxide layer and a silicon nitride layer.

13. The method according to claim 10, wherein a material of the gate layer comprises at least one selected from a group consisting of molybdenum, tantalum, aluminum and tungsten.

14. The method according to claim 11, wherein a material of the gate layer comprises at least one selected from a group consisting of molybdenum, tantalum, aluminum and tungsten.

15. The method according to claim 12, wherein a material of the gate layer comprises at least one selected from a group consisting of molybdenum, tantalum, aluminum and tungsten.
